(19) United States
(12) Patent Application Publication
(10) Pub. No.: US 2007/0001320 A1
(43) Pub. Date: Jan. 4, 2007

(54) Bonding apparatus and method

(75) Inventor: Toru Maeda, Tachikawa-shi (JP)

Correspondence Address: KODA & ANDROLIA, 2029 CENTURY PARK EAST, SUITE 1140, LOS ANGELES, CA, 90067, US

(73) Assignee: Kabushiki Kaisha Shinkawa

(21) Appl. No.: 11/480,179

(22) Filed: Jun. 30, 2006

(30) Foreign Application Priority Data
Jun. 30, 2005 (JP) 2005-192426

(51) Int. Cl. H01L 23/48

(52) U.S. Cl. 257/786

(57) ABSTRACT

A wire bonding apparatus 10 including an XYZ drive mechanism 20 for moving a bonding arm 21 that has a bonding capillary 24 at its tip end, an XYZ drive mechanism 30 for driving a plasma arm 31 that has a plasma capillary 40 having a high-frequency coil wound at its tip end portion end, a gas supply unit 60 for supplying gas to the plasma capillary, and a high-frequency power supply unit 80 for supplying high-frequency electric power to the high-frequency coil. With a supply of high-frequency electric power to the high-frequency coil, gas is being a plasma inside the plasma capillary and is ejected from its tip end against a bonding subject 8, thus performing surface treatment on the bonding subject; and using the bonding capillary, bonding is performed interconnectedly with this surface treatment.

### BACKGROUND OF THE INVENTION

The present invention relates to a bonding apparatus and method and more particularly to a bonding apparatus and method for executing a bonding process after performing a surface treatment on a bonding subject on which bonding is executed.

Bonding apparatuses are generally for making connections between chip electrode units and circuit board lead terminals with fine metal wires. Chip electrode units connected by fine metal wires are sometimes called bonding pads, and circuit board lead terminals are sometimes called bonding leads. When fine metal wires are connected to these elements using ultrasonic connection technology or thermo-compression bonding or the like, it is important to know surface conditions thereof. More specifically, when the surface of either the metal layer of a bonding pad or the metal layer of a bonding lead is contaminated, or foreign matter is present thereon, then it is not possible to obtain a good electrical junction between such surface and the fine metal wire, and the strength of the mechanical junction is also weak. As a result, attempts are made to perform surface treatments on bonding pads or bonding leads before performing bonding processes.

In Japanese Patent Application Laid-Open Disclosure (2000) No. 2000-340599, for example, an apparatus for effecting wire bonding after cleaning the surface to be connected is disclosed, and a wire bonding apparatus 12 integrally comprised of a plasma jet unit 50 and a wire bonding unit 51 is described therein. The plasma jet unit has a concentric double structure comprising an outer dielectric tube 23 and an inner dielectric tube 22. A grounded conical electrode 27 is provided in the outer dielectric tube, and a rod-shaped high-frequency electrode 26 is provided in the interior of the inner dielectric tube, respectively, and, therebetween, after introducing argon gas, for example, an intra-atmospheric glow discharge is induced, and a low-temperature plasma is generated. The plasma generated in this manner is ejected from a gas ejection port, exposed on an electrode on a BGA board, the contamination thereupon is removed, and, thereafter, wire bonding is performed.

In Japanese Patent Application Laid-Open Disclosure (1999) No. H11-260597, which is corresponding to U.S. Pat. No. 6,429,400 B1, a plasma processing apparatus is disclosed, and the cooling the central electrode 3 and the outer electrode 1 and the like are described therein as a method of suppressing streamer discharges in order to perform a plasma process by a stabilized glow discharge. A system using this plasma processing apparatus is described which performs surface treatments on a plurality of bonding pads enclosing electronic components on IC-mounted circuit boards transported by a belt conveyor. Therein, the coordinates of the bonding pads of the boards are read in, the jetting position of plasma jet is controlled according to those coordinates, and, by sequential feeding, only the bonding pads are subjected to plasma processing.

In Japanese Patent Application Laid-Open Disclosure (2003) No. 2003-328138, a microplasma CVD apparatus is disclosed in which a high-frequency coil 7 is provided at the narrowed tip of a tubular plasma torch 5 formed of an insulating material 3, and a wire is passed inside the plasma torch; and induction plasma is generated by high-frequency electric power between the high-frequency coil in the plasma torch and the wire. It is further described that the diameter at the tip of the plasma torch is 100 μm or so; and in a 200 μm or so area, materials such as graphite and glassy carbon are built up in the atmosphere using a high-density microplasma.

The technologies described in Japanese Patent Application Laid-Open Disclosure Nos. 2000-340599 and H11-260597 use gas being a plasma by glow discharge. This method is a capacitively coupled plasma generating method, and involves electrical discharges; accordingly, there are effects damage to electronic devices. In reality, the embodiments described in Japanese Patent Application Laid-Open Disclosure Nos. 2000-340599 and H11-260597 are limited to circuit board connection units, that is, to bonding leads.

The technology of Japanese Patent Application Laid-Open Disclosure (2003) No. 2003-328138 uses an induction plasma induced by a high-frequency coil, and hence belongs to the so-called inductively coupled plasma generation methods. Inductively coupled plasma, in general, is a hot plasma, and, with the high plasma temperature as is, electronic devices are damaged. With the microplasma technology of Japanese Patent Application Laid-Open Disclosure (2003) No. 2003-328138, technology is disclosed for stably generating this hot plasma in an extremely narrow space, based whereupon, small, limited areas can be irradiated with plasma, and little thermal damage will be done. From these facts, it is thought possible to use the microplasma technology of Japanese Patent Application Laid-Open Disclosure (2003) No. 2003-328138 in surface treatment prior to bonding processing.

For wire bonding apparatuses, meanwhile, the current demands for higher precision and higher speed are strong, and, in the movement of bonding heads for holding wires and performing bonding processes, high-precision positioning is performed at high speed. Accordingly, in order to perform surface treatment prior to bonding processing, the unique demands of such a bonding apparatus made to operate at high speed must be taken into consideration. Japanese Patent Application Laid-Open Disclosure Nos. H11-260597 and 2003-328138 do not give consideration to the relationship with bonding processing, and, in Japanese Patent Application Laid-Open Disclosure (2000) No. 2000-340599, no specific content for an integrated configuration for a plasma jet unit and a wire bonding unit is discussed.

As seen from the above, in the bonding apparatuses of the conventional art, it is very difficult to perform surface treatment that is efficient, with the relationship with bonding processing.

### BRIEF SUMMARY OF THE INVENTION

Accordingly, it is an object of the present invention to provide a bonding apparatus and method capable of efficiently performing surface treatments and bonding processing on bonding subjects on which bonding is executed.

It is another object of the present invention to provide a bonding apparatus and method that makes it possible to effect surface treatments on bonding subjects using microplasma.

The above objects are accomplished by a unique structure for a bonding apparatus that includes a bonding processor, a plasma capillary and an inductively coupled microplasma generator and in this structure: the bonding processor executes a bonding process on a bonding subject using a bonding tool; the plasma capillary having a high-frequency coil wound on a tip end portion thereof and the inductively coupled microplasma generator includes the plasma capillary and performs a surface treatment on the bonding subject and ejects gas being a plasma in an interior of the plasma capillary by supply of electric power to the high-frequency coil of the plasma capillary, from an opening at the tip end portion of the plasma capillary onto the bonding subject

The above object is further accomplished by another unique structure of the present invention for a bonding apparatus that is comprised of a bonding processor, a plasma capillary, a plasma processor and a controller; and in this structure: the bonding processor executes a bonding process on a bonding subject using a bonding arm having a bonding capillary; the plasma capillary performs a surface treatment on the bonding subject and this plasma capillary has a high-frequency coil wound on the tip end portion thereof, said this ejects gas being a plasma in the interior of the plasma capillary by supply of electric power to the high-frequency coil thereof, from the opening at the tip end portion thereof onto the bonding subject; the plasma processor performs a surface treatment on the bonding subject using a plasma arm that has the plasma capillary at the tip end of the plasma arm; and the controller interconnectedly controls actions of the bonding arm and actions of the plasma arm.

In the above bonding apparatus of the present invention, it is preferable that the bonding processor perform a bonding process on a bonding subject held on a bonding stage, that the plasma processor perform a surface treatment on a bonding subject that is of the same type as the bonding subject processed by the bonding processor and that is held on a surface treatment stage, and that the controller effect control for interconnectedly executing a bonding process and a surface treatment, respectively, at the same sites on bonding subjects of the same type.

In the bonding apparatus of the present invention, it is preferable that the bonding subject be a chip bonding pad and a board bonding lead, and that the controller effect control for causing the surface treatment conditions for the bonding pad to differ from the surface treatment conditions for the bonding lead.

In the bonding apparatus of the present invention, it is also preferable that the controller effect control for interconnectedly executing a bonding process and a surface treatment on the same bonding subject

Furthermore, it is preferable in the present invention that the controller effect control for causing the bonding arm and the plasma arm to move as a unit.

The above objects are accomplished by a unique step of the present invention for a bonding method using a bonding apparatus, comprising:
providing a bonding apparatus, the bonding apparatus comprising:
   a bonding processor for bonding process on a bonding subject,
   a plasma capillary having a high-frequency coil wound on a tip end portion thereof, and
   an inductively coupled microplasma generator including said plasma capillary and for treating a surface on the bonding subject;
   performing the surface treatment on the bonding subject by ejecting gas being
   a plasma in an interior of said plasma capillary by supply of electric power to the high-frequency coil of said plasma capillary, from an opening at the tip end portion of said plasma capillary onto the bonding subject; and
   executing a bonding process on the bonding subject using a bonding tool.

The above object is further accomplished by another unique step of the present invention for a bonding method using a bonding apparatus, comprising:
providing a bonding apparatus, the bonding apparatus comprising;
   a bonding processor for bonding process on a bonding subject,
   a plasma capillary having a high-frequency coil wound on a tip end portion thereof,
   a plasma processor for treating a surface on the bonding subject using a plasma arm having said plasma capillary at a tip end of the plasma arm, and
   a controller for interconnectedly controlling actions of a bonding arm and actions of the plasma arm;
performing a surface treatment on the bonding subject by ejecting gas being a plasma in an interior of said plasma capillary by supply of electric power to the high-frequency coil of said plasma capillary, from an opening at the tip end portion of said plasma capillary onto the bonding subject;
executing a bonding process on the bonding subject using the bonding arm having a bonding capillary; and
controlling interconnectedly actions of the bonding arm and actions of the plasma arm by said controller.

The above objects are accomplished by a unique step of the present invention for a bonding method comprising the step of:
providing a bonding processor for bonding process on a bonding subject;
providing a plasma capillary having a high-frequency coil wound on a tip end portion thereof;
providing an inductively coupled microplasma generator including said plasma capillary and for treating a surface on the bonding subject;
performing the surface treatment on the bonding subject by ejecting gas being a plasma in an interior of said plasma capillary by supply of electric power to the high-frequency coil of said plasma capillary, from an opening at a tip end portion of said plasma capillary onto the bonding subject and
executing a bonding process on the bonding subject using a bonding tool.

The above object is further accomplished by another unique step of the present invention for a bonding method comprising the step of:
providing a bonding processor for bonding process on a bonding subject;
providing a plasma capillary having a high-frequency coil wound on a tip end portion thereof:
providing a plasma processor for treating a surface on the bonding subject using a plasma arm having said plasma capillary at a tip end of the plasma arm;
providing a controller for interconnectedly controlling actions of a bonding arm and actions of the plasma arm;
performing a surface treatment on the bonding subject by ejecting gas being a plasma in an interior of said plasma capillary by supply of electric power to the high-frequency coil of said plasma capillary, from an opening at the tip end portion of said plasma capillary onto the bonding subject;
executing a bonding process on the bonding subject using the bonding arm having a bonding capillary; and
controlling interconnectedly actions of the bonding arm and actions of the plasma arm by said controller.

With the structures described above, in addition to a bonding processor, the bonding apparatus and method of the present invention is provided with an inductivety coupled microplasma generator that includes a plasma capillary having a high-frequency coil wound on the tip end portion thereof and performs surface treatment by ejecting gas being a plasma in the interior of the plasma capillary by the supply of electric power to the high-frequency coil, onto a bonding subject from the opening in the tip end portion of the plasma capillary. Accordingly, both a bonding processing function and a function for performing surface treatments, with little heat damage, by irradiating the bonding subject in a small area with the microplasma, are involved, and surface treatment and bonding processing are efficiently performed on the bonding subject.

Furthermore, in the present invention, the action of the bonding arm, which has the bonding capillary, and the action of the plasma arm, which has the plasma capillary, are interconnectedly controlled. Accordingly, it is possible to perform efficient surface treatments with the relationship with the bonding processing. By “interconnectedly” is meant that, instead of batch processing, actions are done simultaneously, in parallel, which meaning is inclusive of actions done synchronously or actions done, if not synchronously, sequentially at substantially the same time, etc.

Furthermore, for the bonding subjects of the same type and for the same sites thereon, for instance, for bonding pads, the bonding processor performs bonding processing at a bonding stage, while the plasma processor performs surface treatments at a surface treatment stage. Accordingly, it is possible to perform bonding processing and surface treatments simultaneously in a parallel fashion. Bonding processing and surface treatments are performed by, for example, similar sequencing software.

Furthermore, in the present invention, the surface treatment conditions for bonding pads and the surface treatment conditions for bonding leads can be made to be different. Accordingly, processing which is suitable, depending upon the surface treatment subject, can be performed.

Furthermore, the bonding processing and surface treatments for the same bonding subject are interconnectedly performed in the present invention. Accordingly, surface treatment and bonding processing are done simultaneously, in parallel, or sequentially, on one chip, for example, and thus it is possible to perform bonding processing immediately after surface treatment.

Furthermore, since the bonding arm and the plasma arm are moved as one unit in the present invention, the movement mechanism can be simple in structure.

As seen from the above according to the bonding apparatus and method of the present invention, it is possible to perform surface treatment and bonding processing on bonding subjects efficiently. It is further possible in the present invention to perform surface treatments on bonding subjects with microplasma.

### BRIEF DESCRIPTION OF THE SEVERAL VIEWS OF THE DRAWINGS

FIG. 1 shows a wire bonding apparatus performing surface treatment and bonding processing according to an embodiment of the present invention;

FIG. 2 shows a plasma arm that includes a plasma capillary at a tip end thereof according to an embodiment of the present invention;

FIG. 3 shows the overall structure of the microplasma generator according to an embodiment of the present invention;

FIG. 4 shows how a microplasma is generated in the interior of the plasma capillary according to an embodiment of the present invention;

FIG. 5 shows how a bonding subject is irradiated by a microplasma according to an embodiment of the present invention;

FIGS. 6(a) through 6(e) show the procedure for interconnectedly performing surface treatment and bonding processing according to an embodiment of the present invention;

FIGS. 7(a) through 7(c) show the actions of a bump bonding apparatus according to an embodiment of the present invention;

FIGS. 8(a) through 8(e) show the actions of a flip chip bonding apparatus according to an embodiment of the present invention;

FIG. 9 shows a single-stage wire bonding apparatus according to an embodiment of the present invention;

FIG. 10 shows an arm used in a single-stage wire bonding apparatus according to an embodiment of the present invention; and

FIG. 11 shows another arm used in a single-stage wire bonding apparatus according to an embodiment of the present invention.

### DETAILED DESCRIPTION OF THE INVENTION

The present invention will be described below in detail with reference to the accompanying drawings.

In the following description, detailed description is given concerning ordinary wire bonding, in particular, for surface treatment and bonding processing related to chip bonding pads and board bonding leads.

Ordinary wire bonding here refers to performing a first wire bonding to a bonding pad on a chip mounted on a substrate, then extending that wire and performing a second bonding on the a bonding lead.

For connection technology relating to bonding pads and bonding leads, in addition to wire bonding technology, depending on the properties of the bonding subjects, wire bonding on stacked devices laminated on chips, technology for forming flip chips, chip on film (COF) technology, ball grid array (BGA) technology, and the like are used. In the following description, as many embodiments as possible will be described in addition to ordinary wire bonding technology, but it should be noted that the present invention is applicable to other surface treatments and bonding processing relating to bonding pads and bonding leads.

As described above, “bonding processing” is here meant connection processing relating to chip bonding pads and board bonding leads, in the wider sense, not simply limited to wire bonding. Accordingly, while the bonding tool used in bonding processing is a capillary that allows a wire to pass therethrough: in the case of wire bonding, that may not always be a capillary in other technologies. In the case of COF, for example, a collet for grasping and bonding the chip is the bonding tool.

In the following description, surface treatment is described basically as applied to both bonding pads and bonding leads, but one or other may be omitted, depending on the properties of the specific bonding subject

In terms of surface treatments, moreover, there are oxidation, reduction, and etching and the like. In the description below, the plasma capillary is assumed to be one, and the content of surface treatment is assumed to be performed by switching the gas supply. However, in order to eliminate gas switching delay, a plurality of plasma capillaries can also be mounted, and used, respectively, for different surface treatments.

### Embodiment 1

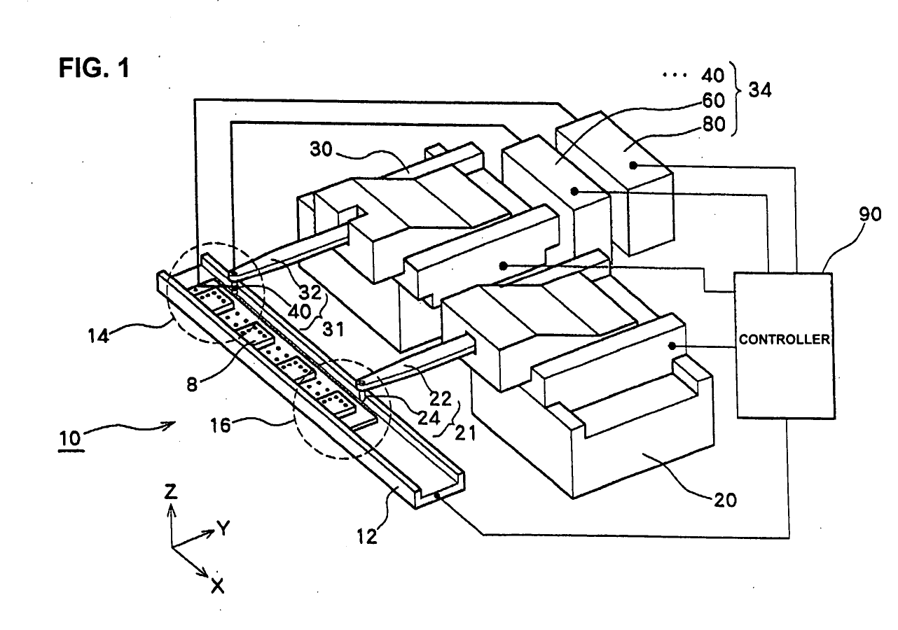

FIG. 1 shows a wire bonding apparatus 10 capable of performing surface treatments and bonding processing. Chips mounted on a substrate are also shown as bonding subjects 8. The wire bonding apparatus 10 has functions for performing a surface treatment by the action of the plasma-state gas, prior to the bonding processing, on a narrow area for performing bonding, specifically on a chip bonding pad and board bonding leads, for a bonding subject 8, and then performing bonding processing.

The wire bonding apparatus 10 is comprised of a transporter mechanism 12 for holding the bonding subject 8 and transporting it to a prescribed position, a bonding arm 21 having a bonding capillary 24 attached to the tip end of a bonding arm main body 22, a bonding XYZ drive mechanism 20 for movement-driving the bonding arm 21, a plasma arm 31 having a plasma capillary 40 attached to the tip end of a plasma arm main body 32, a surface treatment XYZ drive mechanism 30 for movement-driving the plasma arm 31, a surface treatment gas supply unit 60, a surface treatment high-frequency power supply unit 80, and a controller 90 for integrally controlling each of the elements—A microplasma generator 34 is comprised of the plasma capillary 40, gas supply unit 60, and high-frequency power supply unit 80.

The bonding XYZ drive mechanism 20 has functions capable of moving the bonding arm 21 to any desired position in the X axis direction and Y axis direction as shown in FIG. 1, and it also drives the tip end of the bonding capillary 24 up and down in the Z axis direction at that desired position. The bonding arm 21 is comprised of the bonding arm main body 22 and the bonding capillary 24 attached to the tip end thereof. The bonding XYZ drive mechanism 20 is comprised of a high-speed XY table for carrying the bonding arm main body 22 and a high-speed Z motor for slide-driving the bonding arm main body 22 and moving the bonding capillary 24 attached to the tip end thereof up and down. For positioning, a servo mechanism using sensors is used.

The bonding arm 21 is comprised of the bonding arm main body 22 and the bonding capillary 24 attached to the tip end thereof, as described above, and it also has functions for supplying ultrasonic energy to the bonding capillary 24 by an ultrasonic transducer (not shown in the drawings) and pressing the bonding wire passed through the bonding capillary 24 against the bonding subject 8. The bonding capillary 24, as is commonly known, is a narrow tubular member through which a bonding wire passes. A narrow wire of metal or aluminum or the like can be used as the bonding wire. In FIG. 1, mechanisms such as a spool for supplying the bonding wire, or a damper for clamping and releasing the bonding wire to control the movement of the bonding wire, are omitted from the drawing.

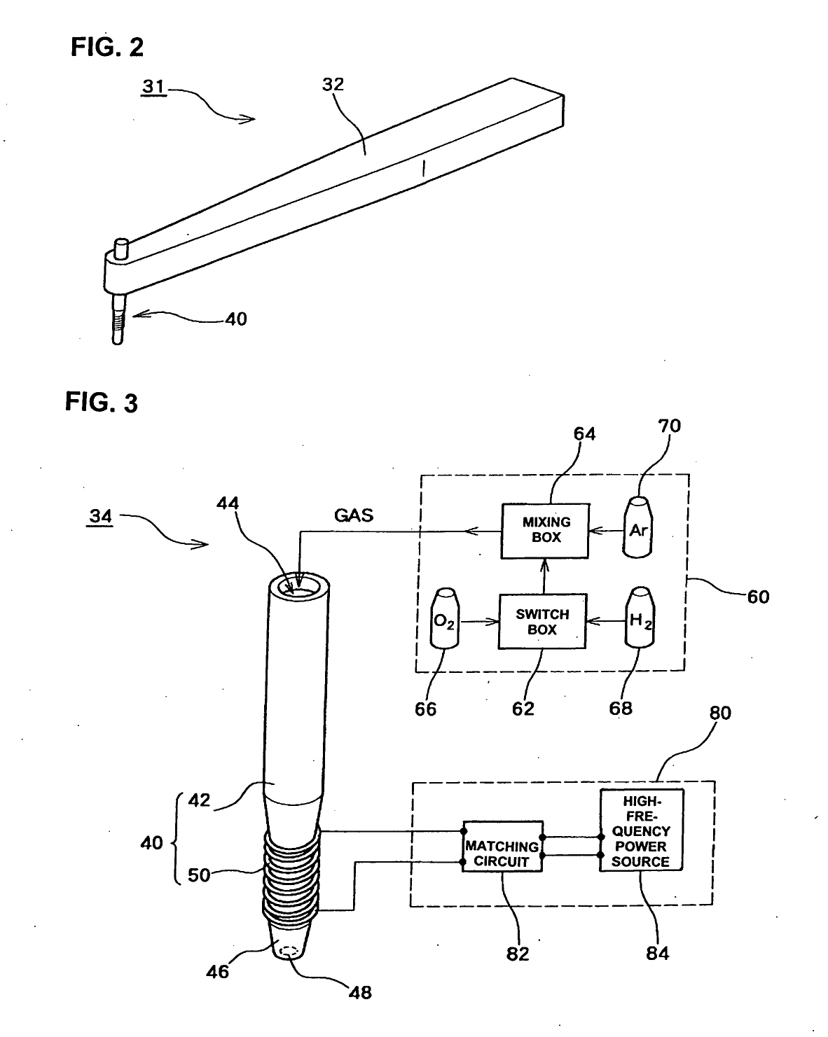

The surface treatment XYZ drive mechanism 30 has functions for moving the plasma arm 31 having at the tip end thereof the plasma capillary 40 for surface treatment, subsequently described in detail, to any desired position in the X axis direction and Y axis direction indicated in FIG. 1, and it also moves the tip end of the plasma capillary 40 up and down in the Z axis direction at that desired position. The plasma arm 31 is comprised of the plasma arm main body 32 and the plasma capillary 40 that is attached to the tip end thereof. FIG. 2 shows the plasma arm 31 by itself. Thus the external appearances of the plasma arm main body 32 and the plasma capillary 40 are similar to the outer appearances of the bonding arm main body 22 and the bonding capillary 24, respectively.

The surface treatment XYZ drive mechanism 30 has substantially the same functions as the bonding XYZ drive mechanism 20. What is different is that, whereas the bonding XYZ drive mechanism 20 requires a high-speed, high-precision movement drive, the surface treatment XYZ drive mechanism 30 does not require all that much positioning precision. The reason for this is that the area where surface treatment is applied is wider than the projection area where the wire is connected to a bonding pad or bonding lead, and some degree of variation is also tolerable therein. Accordingly, the performance requirements for the XY table and Z motor configuring the surface treatment XYZ drive mechanism 30 can be relaxed as compared to those for the bonding XYZ drive mechanism 20.

As describe above, the surface treatment XYZ drive mechanism 30, plasma arm main body 32, and plasma capillary 40 have substantially the same functions as the bonding XYZ drive mechanism 20, bonding arm main body 22, and bonding capillary 24. Accordingly, by calibrating the position of the tip end of the plasma capillary 40 and the position of the tip end of the bonding capillary 24, the movement control for both can be executed in the same sequence. In other words, by applying the same sequencing program, the movement of the tip end of the bonding capillary 24 and the movement of the tip end of the plasma capillary 40 relative to the bonding subject 8 can be made altogether the same. More specifically, when the same sequencing program is given simultaneously to the surface treatment XYZ drive mechanism 30 and the bonding XYZ drive mechanism 20, the movement of the tip end of the plasma capillary 40 and the movement of the tip end of the bonding capillary 24 can be made the same. In short, it is as though the two units, that is, the surface treatment apparatus and the bonding apparatus, can be made so that they perform exactly the same movements simultaneously.

Before describing the particulars of the plasma capillary 40, the gas supply unit 60, and the high-frequency power supply unit 80, which constitute the microplasma generator for surface treatment, the remaining elements will be first described.

The transporter mechanism 12 has functions for transporting the bonding subject 8 to a surface treatment stage 14 that is the process area for the plasma capillary 40 and fixing the positioning there, causing the bonding subject 8 to be subjected to surface treatment, and then moving and transporting the bonding subject 8 to a bonding stage 16 that is the process area for the bonding capillary 24, fixing the positioning there, and causing the bonding subject 8 to be subjected to bonding processing. For such a transporter mechanism 12, a mechanism for clamping and moving the object being transported, can be used.

The controller 90 is an electronic circuit unit and is connected to the transporter mechanism 12, the bonding XYZ drive mechanism 20, the surface treatment XYZ drive mechanism 30, the gas supply unit 60, and the high-frequency power supply unit 80, and the like. The controller 90 functions to control those elements so that surface treatment is performed on the bonding subject 8 and then bonding processing is performed. Those functions are executed by software. More specifically, such functions are done by executing a wire bonding program that embodies routines for interconnectedly performing surface treatment and bonding processing. Some of those functions can be effected with hardware.

Next, the detail of the microplasma generator 34 for surface treatment will be described.

FIG. 3 shows the overall structure of the microplasma generator 34—The microplasma generator 34 is comprised of the plasma capillary 40 at the tip end of the plasma arm 31, the gas supply unit 60 connected thereto, and the high-frequency power supply unit 80, as described earlier.

The plasma capillary 40 is a member having functions for generating a microplasma for surface treatment in the interior of a narrow tubular member comprised of an insulating material, ejecting this from an opening in the tip end thereof and causing the bonding subject to be irradiated therewith. The irradiated surface is limited by the size of the tip end opening of the plasma capillary 40 and is an extremely narrow area; accordingly, the ejected plasma can be called a microplasma. The plasma capillary 40 is comprised of a tubular main plasma capillary body 42 formed of an insulating material and a high-frequency coil 50 wound about the external circumference near the tip end portion 46 thereof.

The main plasma capillary body 42 has a through-hole 44 to which the gas constituting the source of the microplasma is supplied and has substantially the same dimensions and the same shape as the bonding capillary 24 except for the portion about which the high-frequency coil 50 is wound. In one example of dimensions of ordinary capillary, the length is approximately 11 mm, the diameter of the thick portion is approximately 1.6 mm, the diameter on the gas supply side of the through-hole 44 is 0.8 mm, and the diameter of the opening 48 in the tip end is approximately 0.05 mm. For the material thereof, a ceramic such an alumina can be used, as in the bonding capillary 24.

The high-frequency coil 50 wound near the tip end portion 46 is a conducting wire having a winding of a few turns. While not shown in FIG. 3, an igniter for igniting the plasma is positioned in the vicinity of the high-frequency coil.

The gas supply unit 60 has functions for supplying the gas that constitutes the source of the microplasma. More specifically, the gas supply unit 60 is comprised of a switch box 62 for switching the surface treatment gas, a mixing box 64 for mixing the surface treatment gas and the carrier gas, various gas sources, and various pipelines for connecting those and the plasma capillary 40. For the various gas sources here, an oxygen gas source 66 for oxidation treatments, a hydrogen gas source 68 for reduction treatments, and an argon gas source 70 for the carrier gas are used, respectively.

The switch box 62 has functions for switching between the oxygen gas source 66 and the hydrogen gas source 68, depending on whether the surface treatment is oxidation or reduction, and sending oxygen or hydrogen gas at a suitable flow volume to the mixing box 64. The mixing box 64 has mixes the oxidation gas or reduction gas sent from the switch box 62 with the carrier gas, in a suitable mixture ratio and supplies this to the through-hole 44 in the plasma capillary 40. The control of the switch box 62 and the mixing box 64 is conducted by the controller 90. Since the quantity of gas consumed is a very small quantity, small gas tanks can be used for the gas sources. Needless to say, the switch box 62 and the mixing box 64 can be connected by dedicated pipelines from external gas sources.

When oxygen gas is used as the surface treatment gas source, foreign matter including organic matter on the surface of the bonding subject can be removed by oxidation. When hydrogen gas is used as the surface treatment gas source, an oxidized film on the surface of the bonding subject can be removed by reduction. Other than this, depending on the bonding subject, a fluorine-based etching gas may also be used as the surface treatment gas source. The properties of the microplasma can be switched according to the bonding subject, so that, for example, for bonding pads, hydrogen gas is used for removing metal oxide films formed thinly on the surface thereof, while, for bonding leads, oxygen gas is used for removing organic matter adhering to the surface thereof.

The high-frequency power supply unit 80, which has functions for supplying high-frequency electric power to the high-frequency coil 50 wound on the plasma capillary 40, for sustaining the generation of the microplasma, is comprised of a matching circuit 82 and a high-frequency power source 84. The matching circuit 82 is a circuit for suppressing power reflection when supplying the high-frequency power to the high-frequency coil 50, for which, for example, circuitry configuring an LC resonant circuit between the high-frequency coil 50 is used. For the high-frequency power source 84, a power supply having a frequency of 13.56 MHz or 100 MHz, for example, can be used. The level of the power supplied is determined giving consideration to the type and flow volume of the gas supplied from the gas supply unit 60, and the microplasma stability, and the like—The control of the high-frequency power source 84 is performed by the controller 90.

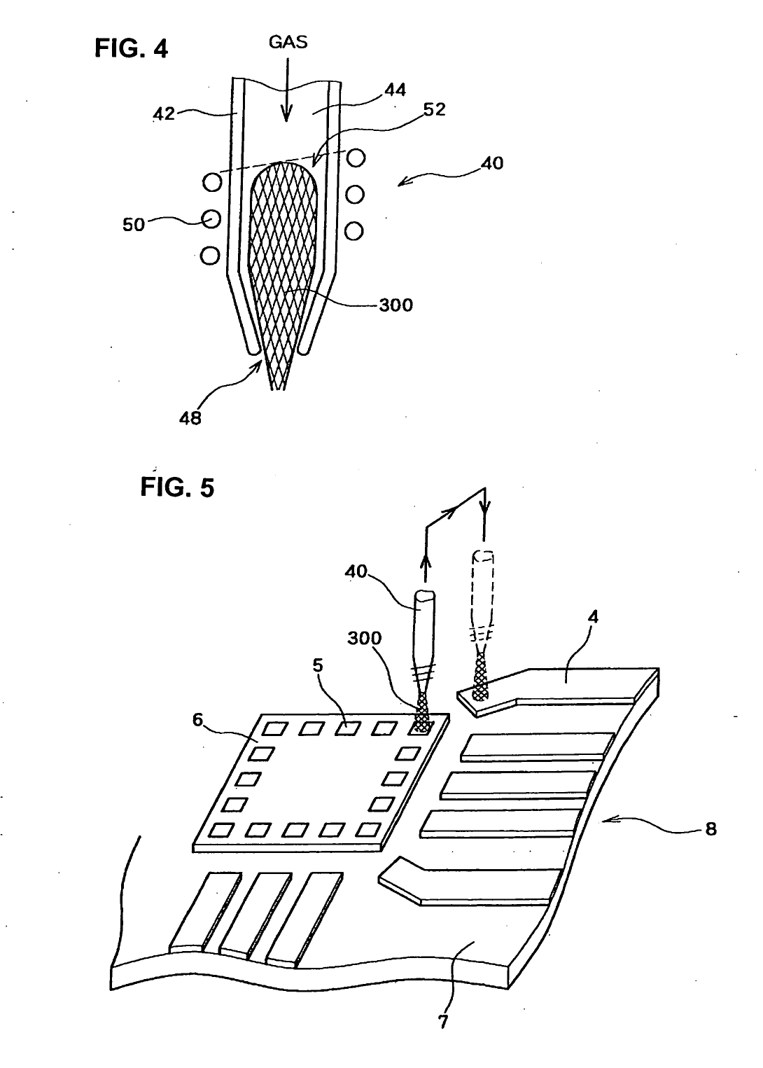

FIG. 4 shows the manner of a microplasma 300 generated in the interior of the plasma capillary 40 by the action of the microplasma generator 34. To generate the microplasma 300, the following procedures are conducted. First, the gas supply unit 60 is controlled, and gas, of a suitable gas type and at a suitable flow volume, is supplied to the through-hole 44 in the plasma capillary 40. The supplied gas flows from the opening 48 in the tip end to the outside. Next, the high-frequency power supply unit 80 is controlled, and suitable high-frequency power is supplied to the high-frequency coil 50. These suitable conditions can be found beforehand by experiment. Then ignition is effected by the igniter (not shown). If the supplied gas conditions and the high-frequency power conditions are suitable, induction plasma is generated by the high-frequency power in the flowing gas. In other words, the plasma is igniting. The plasma region 52 in which the supplied gas is being a plasma is, roughly, on the gas downstream side from the position where the high-frequency coil 50 is deployed. The microplasma 300 generated is ejected from the tip end opening 48 of the plasma capillary 40.

In the example dimensions described above, the diameter of the opening 48 is about 0.05 mm; as a result, by suitably taking the distance to the bonding subject, it is possible to have only the narrow area of the bonding pad and bonding leads irradiated by the microplasma 300. Furthermore, even with the microplasma 300 being ejected, if the bonding subject is withdrawn far from, the microplasma 300 is not act on the bonding subject. Accordingly, by raising and lowering the plasma capillary 40, the action of the microplasma 300 on the bonding subject can be controlled. FIG. 5 is a diagram that shows how this works, in which the bonding subject 8 is indicated as a chip 6 mounted on a circuit board 7. It is also shown how, moving the position of the plasma capillary 40 by suitably controlling the surface treatment XYZ drive mechanism 30, irradiation with microplasma 300, respectively, from the plasma capillary 40, is done at the positions of the bonding pad 5 on the chip 6, and the bonding lead 4 on the circuit board 7.

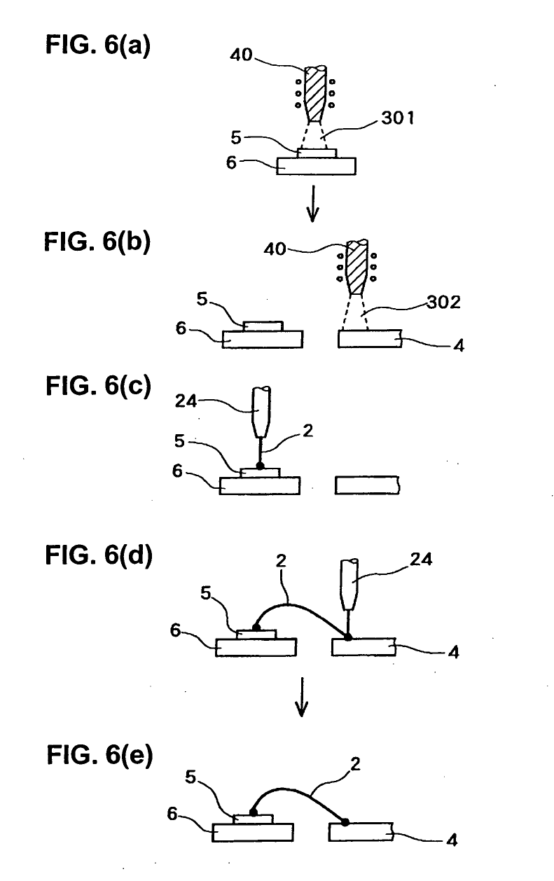

The actions of the wire bonding apparatus 10 configured as per the foregoing will be described below with reference to FIG. 6. FIG. 6 is a process step diagram of procedures for interconnectedly performing surface treatment and bonding processing.

To perform wire bonding, the wire bonding apparatus 10 is started up, and the bonding subject 8 is transported by the transporter mechanism 12 to the surface treatment stage 14 and positioned (surface treatment positioning step).

Then, by command from the controller 90, the microplasma generator 34 is started up, and the microplasma 300 is ignited and generated in the plasma capillary 40. The gas type may be made only the carrier gas, and the surface treatment gas not yet mixed En. At this time, the plasma capillary 40 is distantly separated from the bonding subject 8, and the microplasma 300 is not acting at all (microplasma generation step).

Next, when the wire bonding program is started up, the same positioning as in the bonding stage 16 is effected in the surface treatment stage 14, and the plasma capillary 40 is moved to a high position directly above the first bonding pad 5 (bonding pad positioning step). Then, by command from the controller 90, the gas type is made the reducing gas, that is, hydrogen, which is mixed together with the carrier gas, and the microplasma is made a reducing microplasma 301 (microplasma setting step).

The wire bonding program next lowers the plasma capillary 40 toward the bonding pad 5. Here, the position of the tip end of the plasma capillary 40 is offset beforehand by the measure of the height of the action of the reducing microplasma 301 from the position of the tip end of the bonding capillary. By having this done, when the wire bonding program performs the processing for effecting the first bonding, the tip end of the plasma capillary 40 will stop, exactly above this bonding pad 5, at a height at which the reducing microplasma 301 will optimally irradiate this bonding pad 5. Thereupon, the reducing microplasma 301 wilt remove the thin oxidized film on the surface of the bonding pad 5 and effect a clean surface (bonding pad surface treatment step). How this is done is shown in FIG. 6(a).

Next, the wire bonding program pulls the plasma capillary 40 upward and moves it to directly above the bonding lead 4 (bonding lead positioning step). Then, by command from the controller 90, the gas type is made the oxidizing gas, that is, oxygen, which is mixed together with the carrier gas, and the microplasma is made an oxidizing microplasma 302 (microplasma setting step).

The wire bonding program next lowers the plasma capillary 40 toward the bonding lead 4. Then, the tip end of the plasma capillary 40 stops, exactly above that bonding pad 5, at a height whereat the oxidizing microplasma 302 will optimally irradiate this bonding pad 5. Thereupon, the oxidizing microplasma 302 removes organic foreign matter from the bonding lead 4 (bonding lead surface treatment step). How this is done is shown in FIG. 6(b).

Thereafter, in conjunction with the advance of the wire bonding program, the controller 90 controls the microplasma generator 34 and, by switching between the characteristics of the reducing microplasma 301 and the oxidizing microplasma 302, surface treatment on the bonding pads 5 and bonding leads 4 progresses, sequentially. Then, when the wire bonding program has finished, all of the bonding pads 5 and all of the bonding leads 4 of the bonding subject 8 are surface-treated (surface treatment finishing step).

Next, by command from the controller 90, the transporter mechanism 12 transports the bonding subject 8 on which surface treatment has finished to the bonding stage 16 and positions it (bonding processing positioning step). Then, the wire bonding program is started up, and, as is commonly known, first bonding is performed on the bonding pad 5, after which second bonding is performed on the bonding lead 4. How this is done is shown in FIGS. 6(c) and 6(d). At this time, the surface oxidized film has been removed beforehand from the bonding pad 5, and organic foreign matter on the surface of the bonding lead 4 has been removed, so that bonding processing can be performed stably. How the bonding processing is performed in this way is shown in FIG. 6(e). This is repeated, and, when the wire bonding program finishes, bonding processing relating to all of the bonding pads 5 and all of the bonding leads 4 on the bonding subject 8 finishes (bonding processing finishing step).

In the foregoing description, surface treatment on the bonding pad 5 is described as an oxidized film removal using the reducing microplasma 301, and surface treatment on the bonding lead 4 is described as organic matter removal using the oxidizing microplasma 302; however, these treatments can combined according to the properties of the bonding subject 8, or some other selection may be made. Such gas type setting can be made something that the user can select, as an input to the controller 90.

### Embodiment 2

The microplasma generator 34 shown in FIG. 3 can be applied to a bump bonding apparatus. A bump bonding apparatus is an apparatus for forming metal bumps in flip chip technology. More specifically, such an apparatus uses the principle of wire bonding to a bonding pad on a chip to bond metal wires and make those metal bumps. Thus it might be characterized as equivalent to an ordinary wire bonding process from which the second bonding is eliminated. Accordingly, such an apparatus corresponds to the wire bonding apparatus 10 shown in FIG. 1, in which the bonding subject 8 transported by the transporter mechanism 12 has been made a completed wafer on which completed LSIs are arrayed.

When the bonding subject 8 is a completed wafer, in the surface treatment stage 14, bonding pads 5 are surface-treated, respectively, for a plurality of completed LSIs. Then, when surface treatment on all of the bonding pads has been completed for one completed wafer, the bonding subject 8 is transported to the bonding stage 16. There, bumps are formed for bonding pads 5, respectively, for the plurality of completed LSIs. In this case also, as described relative to FIG. 6, processing can be standardized (or made common), applying the bump bonding program employed in the bonding XYZ drive mechanism 20 similarly to the surface treatment XYZ drive mechanism 30.

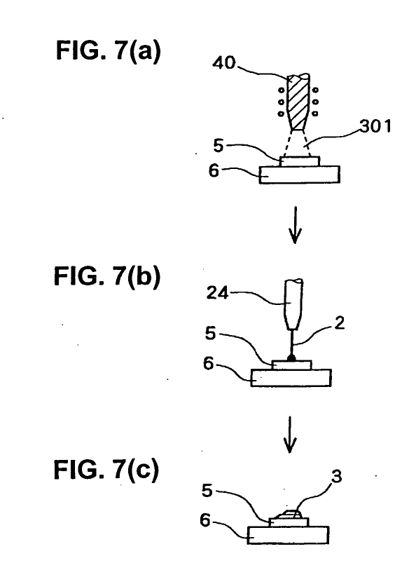

The actions of a bump bonding apparatus configured with the same constituting elements as the wire bonding apparatus 10 shown in FIG. 1, excluding the transporter mechanism 12, will be described below with reference to the steps shown in FIGS. 7(a) through 7(c). Surface treatment is performed, in the surface treatment stage 14, using the plasma capillary 40. Here, the gas type is made hydrogen, and the microplasma is set to the reducing microplasma 301.

Then, by applying the bump bonding program to the surface treatment XYZ drive mechanism 30, at the first LSI position, the plasma capillary 40 comes to directly above the first bonding pad 5 thereof. Next, the plasma capillary 40 descends, and the tip end of the plasma capillary 40 stops, exactly above the bonding pad 5 thereof, at precisely a height whereat the reducing microplasma 301 will optimally irradiate this bonding pad 5. Thereupon, the reducing microplasma 301 removes the thin oxidized film from the surface of the bonding pad 5 (bonding pad surface treatment step). How this is done is shown in FIG. 7(a). The particulars of this step are the same as those described relative to FIG. 6(a).

Thereafter, in conjunction with the advance of the bump bonding program, the bonding pads 5, respectively, at each position of the LSIs, are sequentially surface-treated. Then, when the wire bonding program has finished, all of the bonding pads 5 of the bonding subject 8 are surface-treated (surface treatment finishing step).

Next, by command from the controller 90, the transporter mechanism 12 transports the completed wafer, for which surface treatment has finished, to the bonding stage 16 and positions it (bonding processing positioning step). Then, the bump bonding program is started up, and, at the position of the first LSI, on the first bonding pad 5 thereof, a metal wire is bonded to form a metal bump. How this is done is shown in FIG. 7(b). At this time, the surface oxidized film has been removed beforehand in the bonding pad 5; as a result, bonding processing can be performed more stably. How the metal bump 3 is formed, with the bonding processing finished in this manner, is shown in FIG. 7(c). This is repeated, and metal bumps 3 are formed on all of the bonding pads 5 in all of the LSIs on one wafer.

### Embodiment 3

The microplasma generator 34 shown in FIG. 3 can be applied to a flip chip bonding apparatus. A flip chip bonding apparatus is an apparatus for placing a chip on which a bump is formed as shown in FIGS. 7(a) through 7(c) face down on a circuit board. Accordingly, in such cases, the bump 3 on the chip 6 and the bonding lead 4 connected. Furthermore, the chip is inverted in order to place it face down, and the bonding tool for effecting facedown bonding is not a bonding capillary but a collet for holding the chip placed face down. Thus the specific configuration of a flip chip bonding apparatus differs considerably from that of a wire bonding apparatus.

There are two stages in applying the microplasma generator 34 in a flip chip bonding apparatus, namely when surface-treating the chip bump 3, before inverting the chip and holding it with the collet, and when surface-treating the bonding lead 4 before effecting facedown bonding with the collet

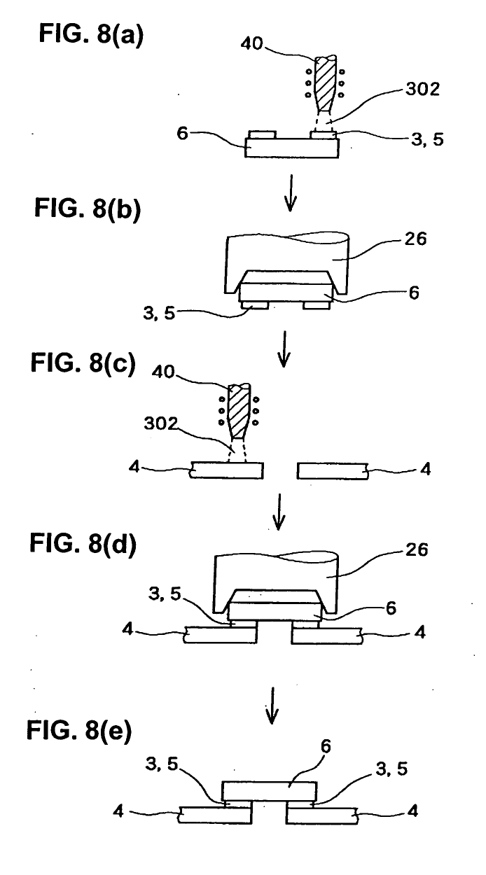

FIGS. 8(a) through 8(e) show the procedures when applying the microplasma generator 34 in a flip chip bonding apparatus.

First, the bump 3 on the bonding pad 5 of the chip 6 is irradiated with a microplasma from the plasma capillary 40. The gas type at this time can be made oxygen, for example, and the oxidizing microplasma 302 used—Depending on the case, the gas type may be made hydrogen, and the reducing microplasma 301 used. How this is done is shown in FIG. 8(a).

Then the chip 6 whereon surface treatment has been finished is inverted and held in a facedown condition by the collet 26. By a facedown condition is meant having the bump 3 facing downward. The holding of the chip 6 with the collet 26 can be done by vacuum suction. How this is done is shown in FIG. 8(b).

Then, next, the bonding lead 4 on the circuit board is subjected to surface treatment The gas type at this time can be made oxygen, for example, and the oxidizing microplasma 302 used. Depending on the case, the reducing microplasma 301 may also be selected. How this is done is shown in FIG. 8(c).

The chip 6 held face down is positional relative to this bonding lead 4, and facedown bonding is performed. How this is done is shown in FIG. 8(d). FIG. 8(e) shows the bump 3 on the chip 6 is connected to the bonding lead 4.

In flip chip technology, when the circuit board is a film board, it is called chip on film (COF). In one technology in such cases, low-temperature solder is provided on the bonding lead, and connection between the bonding lead and the bump 3 is made by thermo-compression bonding. At such time, the surface treatment on the bonding lead 4 side may be omitted, and surface treatment performed only on the bump 3.

### Embodiment 4

In the embodiments described above, a surface treatment stage and a bonding stage are provided, respectively, and, therein, using a surface treatment XYZ drive mechanism and a bonding XYZ drive mechanism, respectively, a plasma arm and a bonding arm are interconnectedly activated, that is, a plasma capillary and a bonding capillary are interconnectedly activated—In other words, surface treatment and bonding processing are performed in parallel on separate objects on a bonding subject of the same type.

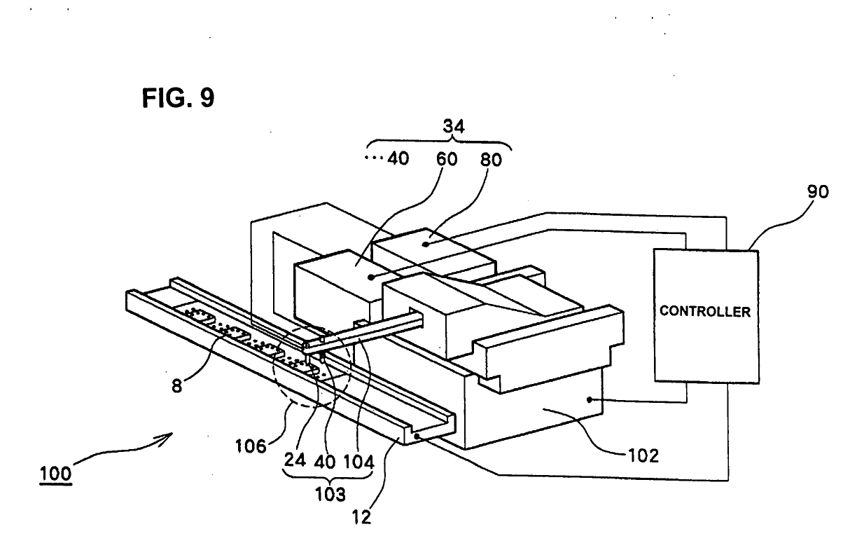

In contrast therewith, it further is possible to perform surface treatment and bonding processing interconnectedly on objects on the same bonding subject, on the same process stage. FIG. 9 shows a configuration of a single-stage bonding apparatus 100 that includes one XYZ drive mechanism 102, one arm 103, and one process stage 106. In the sense of making comparisons, the wire bonding apparatus 10 shown in FIG. 1 can be called a dual-stage type. In the following description, those elements that are the same as those in FIG. 1 will be given the same symbols, and further description thereof will not be given.

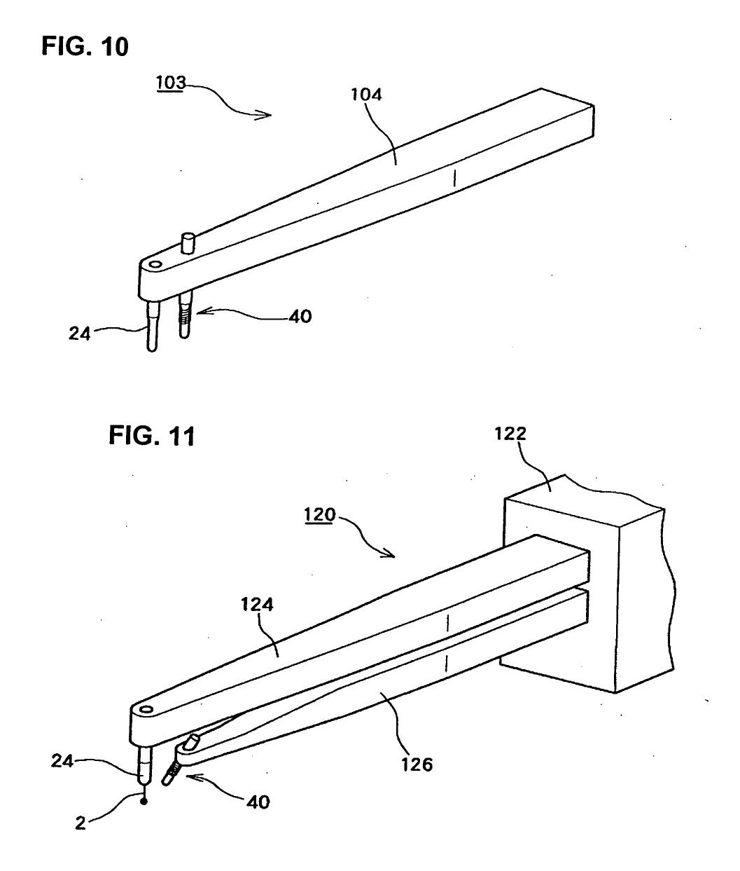

In the single-stage bonding apparatus 100, the arm 103 has both the bonding capillary 24 and the plasma capillary 40 attached to one main arm body 104 as shown in FIG. 10, Here, the configuring of the microplasma generator 34 with the plasma capillary 40, the gas supply unit 60, and the high-frequency power supply unit 80, and the particulars thereof, are the same as described relative to FIG. 3.

As seen from FIG. 10, one arm 103 has a bonding capillary 24 and a plasma capillary 40; as a result, one XYZ drive mechanism suffices, and the configuration can be simple in structure. In this case, the surface treatment and bonding processing procedures can in general be done reciprocally, one after the other. For example, for one bonding pad, the plasma capillary 40 is positioned and bonding pad surface treatment is performed, then, after that, the arm 103 is moved, the plasma capillary 40 is positioned for the corresponding bonding lead, and the bonding lead is subjected to surface treatment. When the surface treatment has finished on a bonding pad and a bonding lead constituting one set, in this manner, next the arm 103 is moved, the position of the bonding capillary 24 is returned to where that bonding pad is, and first wire bonding is performed, the position of the bonding capillary 24 is next moved to where that bonding lead is, and then second bonding is performed.

In other words, the procedures shown in FIGS. 6(a) through 6(e) in which the action of the dual-stage wire bonding apparatus 10 is described are repeated. These procedures are done such that surface treatment and bonding processing are alternated, in the manner of surface treatment→bonding processing→surface treatment→bonding processing, and this is done successively for each set of bonding pad and bonding lead. With this method, for bonding pads and bonding leads, after the surface treatment thereof, the time up to bonding processing can be shortened, and bonding can be performed in which the opportunity for an oxidized film or foreign matter or the like to again adhere after surface treatment is reduced.

In the construction shown in FIG. 10, both the bonding capillary 24 and the plasma capillary 40 are deployed on one main arm body 104 such that they are proximate and in parallel. By attaching the plasma capillary 40 so that it is inclined relative to the bonding capillary 24, making the point toward which the bonding capillary 24 is oriented and the point toward which the plasma capillary 40 is oriented to be substantially the same, the movement mechanism for the arm 103 is made even simpler. In other words, without moving the arm 103, for the same bonding pad and bonding lead, surface treatment can be performed, effecting irradiation with a microplasma from the plasma capillary 40, after which the generation of the microplasma can be stopped, and the wire bonded using the bonding capillary 24.

In the configuration of FIG. 10, both the bonding capillary 24 and the plasma capillary 40 are attached to one main arm body 104; as a result, when the main arm body 104 also serves as a horn for efficiently transmitting ultrasonic energy to the tip end thereof, it is possible that the efficiency of that energy transmission will not always be ideal, due to the existence of the plasma capillary 40. Accordingly, the wire bonding apparatus that includes the structure of FIG. 10 is suitable for a system in which ultrasonic energy is not employed, as in the case of, for instance, a thermo-compression bonding system. Application is also possible in apparatuses in which thermo-compression bonding is aided by ultrasonic energy.

FIG. 11 shows an example of another arm configuration in a single-stage wire bonding apparatus. In the arm 120 in this apparatus, a common base unit 122 is provided, and two main arm bodies, namely a bonding arm main body 124 for the bonding capillary 24 and a plasma arm main body 126 for the plasma capillary 40, are attached separately so as not to interfere with each other. The base unit 122 is attached to a common XYZ drive mechanism.

In the structure of FIG. 11, even in a bonding apparatus of a type in which bonding processing is performed mainly with ultrasonic energy, the shape of the bonding arm main body 124 can be set optimally, eliminating the effects of the plasma capillary 40.

FIG. 11 shows a case in which the plasma capillary 40 is attached so as to be inclined relative to the bonding capillary 24, with the point toward which the bonding capillary 24 is oriented and the point toward which the plasma capillary 40 is oriented made substantially the same. With this structure, as described above, the movement drive for the arm 120 can be made even simpler. The bonding capillary 24 and plasma capillary 40 may of course also be deployed in parallel.

The invention may be embodied in other specific forms without departing from the sprit or essential characteristics thereof. The present embodiment is therefore to be considered in alt respects as illustrative and not restrictive, the scope of the invention being indicated by the appended claims rather than by the foregoing description and all changes which come within the meaning and range of equivalency of the claims are therefore intended to be embraced therein.

1. A bonding apparatus comprising:
a bonding processor for executing a bonding process on a bonding subject using a bonding tool;
a plasma capillary having a high-frequency coil wound on a tip end portion thereof; and
an inductively coupled microplasma generator including said plasma capillary and for performing a surface treatment on the bonding subject by ejecting gas being a plasma in an interior of said plasma capillary by supply of electric power to the high-frequency coil of said plasma capillary, from an opening at the tip end portion of said plasma capillary onto the bonding subject.

2. A bonding apparatus comprising:
a bonding processor for executing a bonding process on a bonding subject using a bonding arm having a bonding capillary;
a plasma capillary for performing a surface treatment on the bonding subject and having a high-frequency coil wound on a tip end portion thereof, said plasma capillary ejecting gas being a plasma in an interior thereof by supply of electric power to the high-frequency coil thereof, from an opening at the tip end portion thereof onto the bonding subject;
a plasma processor for performing a surface treatment on the bonding subject using a plasma arm having said plasma capillary at a tip end of the plasma arm; and
a controller for interconnectedly controlling actions of the bonding arm and actions of the plasma arm.

3. The bonding apparatus according to claim 2, wherein:
said bonding processor performs a bonding process on a bonding subject held on a bonding stage;
said plasma processor performs a surface treatment on a bonding subject that is of the same type as the bonding subject processed by said bonding processor and is held on a surface treatment stage; and
said controller effects control for interconnectedly executing a bonding process and a surface treatment, respectively, at the same sites on bonding subjects of the same type.

4. The bonding apparatus according to claim 3, wherein:
the bonding subjects are a chip bonding pad and a board bonding lead; and
said controller effects control for causing surface treatment conditions for the bonding pad to differ from surface treatment conditions for the bonding lead.

5. The bonding apparatus according to claim 2, wherein:
said controller effects control for interconnectedly executing a bonding process and a surface treatment on the same bonding subject.

6. The bonding apparatus according to claim 5, wherein:
said controller effects control for causing said bonding arm and said plasma arm to move as a unit.

7. A bonding method using a bonding apparatus, comprising:
providing a bonding apparatus, the bonding apparatus comprising:
a bonding processor for bonding process on a bonding subject,
a plasma capillary having a high-frequency coil wound on a tip end portion thereof, and
an inductively coupled microplasma generator including said plasma capillary and for treating a surface on the bonding subject;
performing the surface treatment on the bonding subject by ejecting gas being a plasma in an interior of said plasma capillary by supply of electric power to the high-frequency coil of said plasma capillary, from an opening at the tip end portion of said plasma capillary onto the bonding subject; and
executing a bonding process on the bonding subject using a bonding tool.

8. A bonding method using a bonding apparatus, comprising:
providing a bonding apparatus, the bonding apparatus comprising:
a bonding processor for bonding process on a bonding subject,
a plasma capillary having a high-frequency coil wound on a tip end portion thereof,
a plasma processor for treating a surface on the bonding subject using a plasma arm having said plasma capillary at a tip end of the plasma arm, and
a controller for interconnectedly controlling actions of a bonding arm and actions of the plasma arm;
performing a surface treatment on the bonding subject by ejecting gas being a plasma in an interior of said plasma capillary by supply of electric power to the high-frequency coil of said plasma capillary, from an opening at the tip end portion of said plasma capillary onto the bonding subject;
executing a bonding process on the bonding subject using the bonding arm having a bonding capillary; and
controlling interconnectedly actions of the bonding arm and actions of the plasma arm by said controller.

9. A bonding method comprising the step of:
providing a bonding processor for bonding process on a bonding subject;
providing a plasma capillary having a high-frequency coil wound on a tip end portion thereof;
providing an inductively coupled microplasma generator including said plasma capillary and for treating a surface on the bonding subject;
performing the surface treatment on the bonding subject by ejecting gas being a plasma in an interior of said plasma capillary by supply of electric power to the high-frequency coil of said plasma capillary, from an opening at a tip end portion of said plasma capillary onto the bonding subject; and
executing a bonding process on the bonding subject using a bonding tool.

10. A bonding method comprising the step of:
providing a bonding processor for bonding process on a bonding subject;
providing a plasma capillary having a high-frequency coil wound on a tip end portion thereof;
providing a plasma processor for treating a surface on the bonding subject using a plasma arm having said plasma capillary at a tip end of the plasma arm;
providing a controller for interconnectedly controlling actions of a bonding arm and actions of the plasma arm;
performing a surface treatment on the bonding subject by ejecting gas being a plasma in an interior of said plasma capillary by supply of electric power to the high-frequency coil of said plasma capillary, from an opening at the tip end portion of said plasma capillary onto the bonding subject;
executing a bonding process on the bonding subject using the bonding arm having a bonding capillary; and
controlling interconnectedly actions of the bonding arm and actions of the plasma arm by said controller.
